(19) United States
(12) Patent Application Publication
(10) Pub. No.: US 2007/0108619 A1
(43) Pub. Date: May 17, 2007

(54) Bonding pad with high bonding strength to solder ball and bump

(76) Inventor: Jun Chung Hsu, Ping-Chen City (TW)

Correspondence Address: LIN & ASSOCIATES INTELLECTUAL PROPERTY, P.O. BOX 2339, SARATOGA, CA, 95070-0339, US

(21) Appl. No.: 11/274,016

(22) Filed: Nov. 15, 2005

(51) Int. Cl. H01L 29/40

(52) U.S. Cl. 257/762; 257/786; 257/779

(57) ABSTRACT

A bonding pad with high bonding strength to a solder ball and a bump includes a carrier, a wiring layer formed on the carrier, a protection layer formed on top of the wiring layer and a solder mask layer surrounded around the protection layer and the wiring layer to form a bonding pad opening. The protection layer is extended outside the bonding pad opening such that when solder are extended into the bonding pad opening, the solder balls engage with side faces defining the bump pad opening as well as the protection layer outside the bump pad opening and a bonding strength between the bonding pad and the solder performance is increased.

### BACKGROUND OF THE INVENTION

1. Field of the Invention

The present invention relates to a bump pad, ball pad, and more particularly to a bonding pad with high bonding strength to a solder ball and a bump. Regardless of different surface finish method in convention thinking, this invention focus on change the geometric figure of pad from 2D to 3D space. If the bonding area between solder and pad are enlarged the bonding strength will be enhanced in the ratio of equality.

2. Description of Related Art

Under the trend of miniaturized electronic devices, openings, such as the opening of the ball pad or the bump pad, of the contacts as well as the solder balls or bosses to be implemented on the bump pad on the carrier are smaller and smaller. For example, the pitch of the BGA bump pad is reduced from 1 mm to 0.4 mm and even to 0.3 mm. The opening of SM bump pad is reduced from 350 μm to 220 μm and the opening of the Flip Chip bump pad is reduced from 100 μm to 80 μm. However, in the trend of miniaturization, packaging encounters a precedent challenge. Because the bonding strength between the solder ball and the bump pad is proportional to the engagement area therebetween, the miniaturization of the electronic elements causes the bonding strength therebetween to reduce, which easily results in the conditions of bad connection, separation and cracks between the solder ball and the bump pad and the occurrence of any one of the above conditions leads to an open circuit on the electrical connection between the bump pad and the solder ball. In order to ensure the sound connection between the solder ball and the bump pad, the combination of the solder ball and the bump pad has to pass tests such as pull strength, chisel test, ball shear test, high temperature storage test and drop test . . . etc. Among the tests, the drop test of Nokia® is the harshest. In the trend of green products, such as RoHS®, due to the no-lead requirement in the soldering process to the electrical contacts, the IR reflow temperature reaches 245-260° C. from 220° C. As a consequence, a great deal of surface treatments can not fulfill multiple reflow and result in ball off or crack issue.

The main surface treatment technique includes three categories: OSP (organic solderability preservatives), ENIG/ENAG, electrolytic Nickel-Gold plating. In the OSP process, it is known that chemical treatment is implemented to protect copper surface so that the copper surface is able to endure high temperature from repetitive reflow and baking during the packaging process. This method suffers from that the thickness of OSP membrane is not easy to monitor, easy to be washed away by water or solvent, and can not endure multiple IR reflow more then 6 times. The second category uses chemical reaction to replace the copper surface to nickel and gold. The shortcoming thereof is that the entire process is not easy to control. That is, the quality of soldering will be affected when the phosphorus is too much and nickel surface is etched by the gold liquid which is to be plated onto the nickel surface when the phosphorus is too little and thus black pad is generated because the bonding strength is weakened, which results in detachment. The third method is using electrolytic plating technique to plate nickel and gold onto the copper surface. The shortcoming thereof is that conducting cables are required because the layout of the cables is difficult to design and is limited to the area requirement. Another factor is that Au layer has a thickness of more than 0.5 μm, during soldering process, the Au will fuse to the solder and results in that the IMC (Intermetallic compound) is brittle. That is, when the volume proportion of Au gets larger in the Tin, the materiality is worse.

### SUMMARY OF THE INVENTION

To overcome the aforementioned disadvantages, the present invention tends to provide a bonding pad with high bonding strength to a solder ball and a bump, which is based on the advantages of the current techniques such as OSP, ENIG, ENAG, Ni/Au plating, and Immersion Tin as well as that the bonding strength is proportional to the engagement area, additional engagement area is generated so that the bonding strength between the solder ball and the bump pad is increased within the limited area.

Another objective of the present invention is that a conductive layer is temporarily employed so that the ball side will transmit the electrical current for plating to the bump pad side to accomplish the purpose of no conductive cables for plating.

Other objects, advantages and novel features of the invention will become more apparent from the following detailed description when taken in conjunction with the accompanying drawings

### BRIEF DESCRIPTION OF THE DRAWINGS

FIGS. 1A and 1B are the first embodiment of the bonding pad structure in accordance with the present invention, in which 1A is x-section view, and 1B is top view;

FIGS. 2A and 2B are the second embodiment of the bonding pad structure in accordance with the present invention, in which 2A is x-section view, and 2B is top view;

FIG. 3 is a schematic view showing the third embodiment of the bonding pad with corolla figure in accordance with the present invention; and

FIGS. 4A and 4B are schematic views showing the fourth embodiment of the bonding pad structure in accordance with the present invention, in which 4A is x-section view, and 4B is top view.

### DETAILED DESCRIPTION OF PREFERRED EMBODIMENT

Currently, the technique used to improve the bonding strength of soldering due to aging of the IMC (intermetallic compound) is based on the surface finish of the bonding pad, which has a lot of difference to the technique of the present invention. The present invention aims at how to increase the bonding strength via addition of engagement area within limited space. In short, the protection layer originally covering the wiring layer is further extended to the solder resistant layer on the bonding pad opening which is composed of the protection layer, the wiring layer and solder resistant layer, such that when the solder are filled into the bonding pad opening, the solder further engage with the side face of the bonding pad opening so as to increase the engagement area and thus the bonding strength is increased. In order to fuse with the advantages of OSP, ENIG, ENAG, Ni/Au plating and Immersion Tin, additional steps are added to the process of the present invention to increase the engagement area.

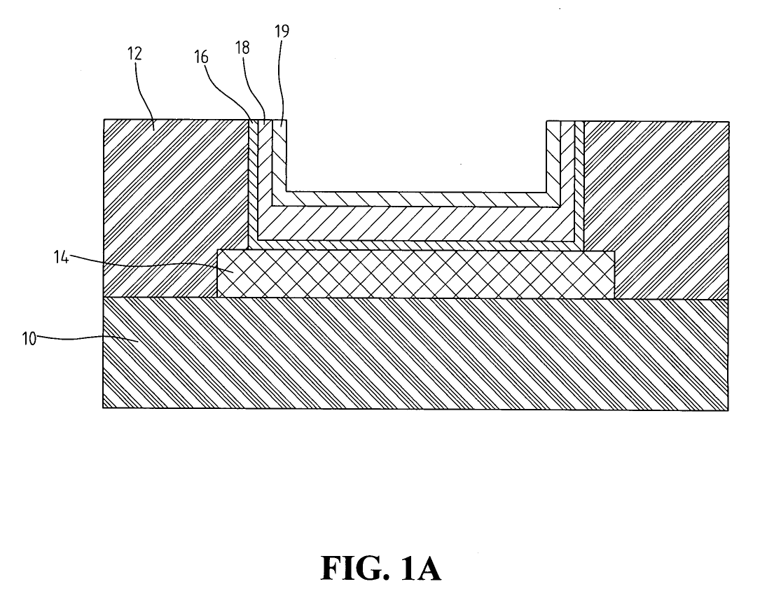

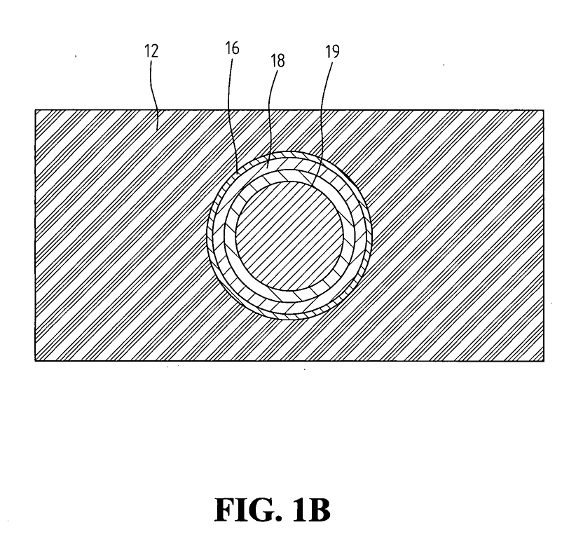

With reference to FIGS. 1A and 1B, if protection is provided to the layer 14 (the bonding pad to be filled with solder) on a carrier 10, normally a copper layer 16, a nickel layer 18 and a gold layer 19 (the protection layer) are sequentially added to the wiring layer 14 and a solder mask layer 12 is surrounded around the protection layer and the wiring layer 14 to form a bonding pad opening. It is to be noted that because the manufacture of the carrier 10 and the protection layer are conventional in the art, detailed description thereof is thus omitted. The description hereinafter will be focused on three embodiments of the present invention, the composition of each metal layer can be changed if further needs.

With reference to FIG. 1A and in order to increase the bonding strength between the solder and the pump/ball pad, a protection layer originally covering the wiring layer 14 is further extended to the solder mask layer on the side wall of bonding pad opening to form a copper layer 16, a nickel layer 18 and a gold layer 19, i.e. the protection layer, such that when the solder are filled into the bonding pad opening, the solder further engage with the side face of the bonding pad opening, as shown in FIG. 1B, so as to increase the engagement area and thus the bonding strength is increased.

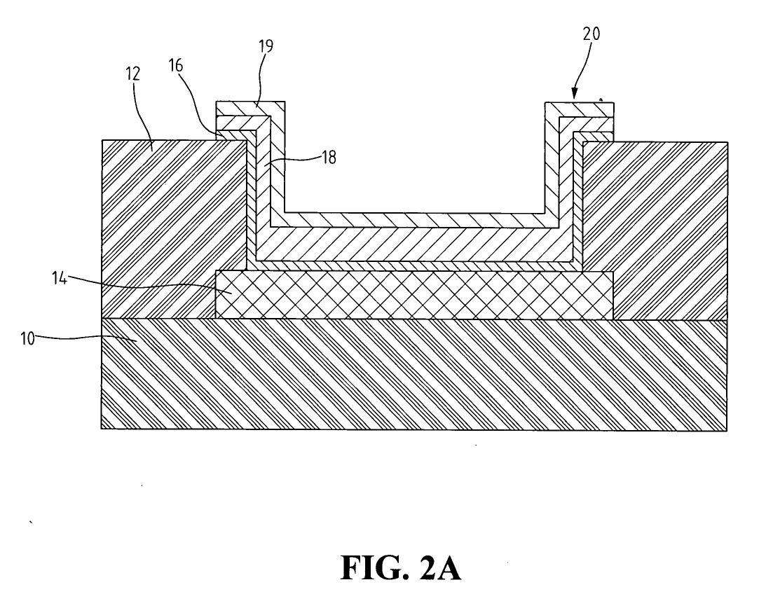

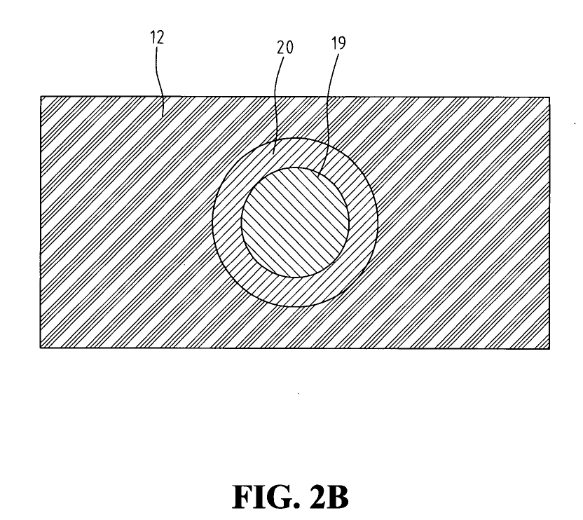

With reference to FIGS. 2A and 2B, a protection layer composed of a copper layer 16 a nickel layer 18 and a gold layer 19 is formed on the wiring layer 14 which is provided on the carrier 10. A solder mask layer 12 is then surrounded the protection layer and the wiring layer 14 to thus form a bonding pad opening and to provide protection thereto. Further, the protection layer is extended outside the surface of bonding pad opening to form an annular extension 20. From the depiction of FIG. 2B, it is observed that only the gold layer 19 is exposed because the gold layer 19 covers the copper layer 16 and the nickel layer 18. Therefore, in addition to the protection layer covering the wiring layer 14 to have direct engagement with the solder, the side face in the bonding pad opening and the annular extension 20 will engage with the solder such that the bonding strength between the solder and the bonding pad is increased.

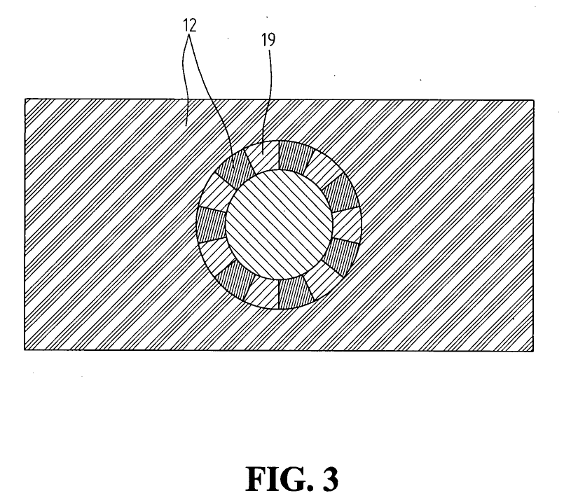

With reference to FIG. 3, a third embodiment of the present invention, it is observed that the annular extension 20 has cutouts defined therein to allow the protection layer to have a configuration of a corona.(when the corona figure and quantity could be defined by designer.) Thus during reflow after the planting of solder balls, the solder will embed the corona layer due to wetting effect. It seems to put the anchor into the solder and enhance the bonding strength dramatically

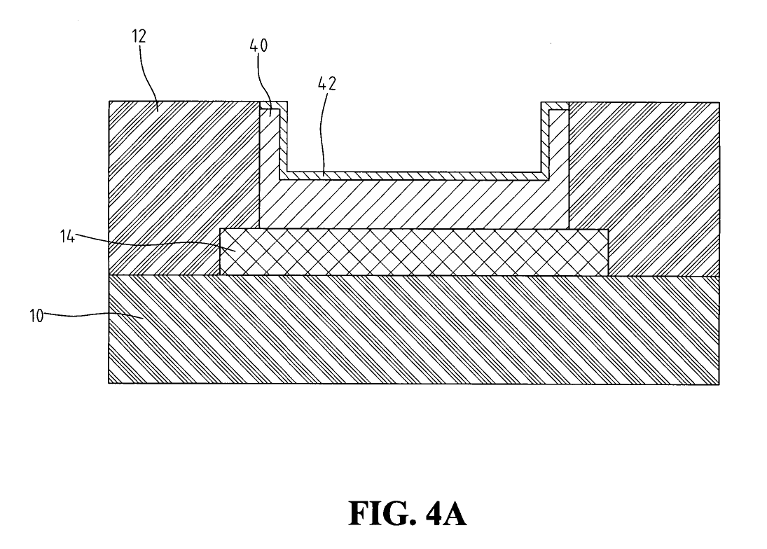

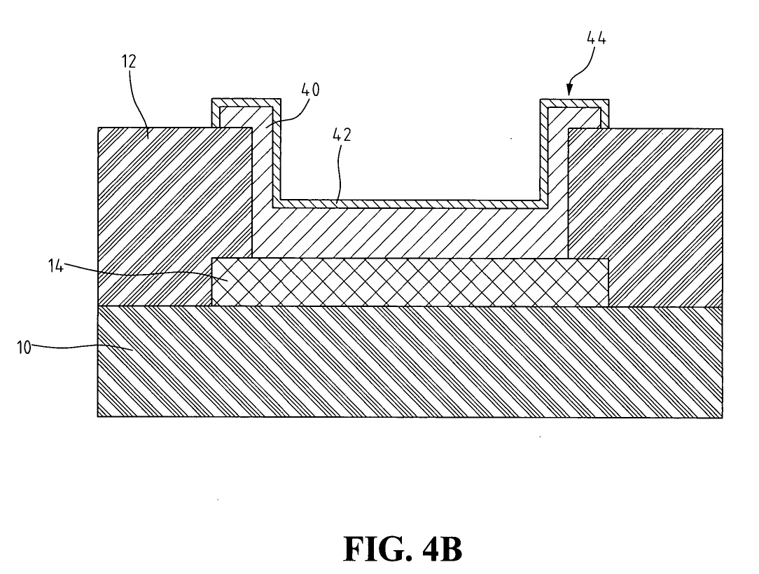

With reference to FIGS. 4A and 4B, a protection layer composed of copper 40 and oxidation resistant membrane 42 is formed on the wiring layer 14 on the carrier 10 via the OSP method and the solder mask layer 12 is surrounded the protection layer and the wiring layer 14 to form a bonding pad opening. However, in addition to the protection layer on the side face of the bonding pad opening, as shown in FIG. 4B, the protection layer is further extended outside the bump pad opening to form an annular extension 44, as shown in FIG. 4B. It is also foreseeable that the annular extension 44 in FIG. 4B may also have cutouts as shown in FIG. 3.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A bonding pad comprising:
a carrier;
a wiring layer formed on the carrier;
a solder mask layer surrounded around the protection layer and the wiring layer to form a bonding pad opening, the protection layer extended outside the bonding pad opening such that when solder are extended into the bump pad opening, the solder engage with side faces defining the bonding pad pad opening as well as the protection layer outside the bonding pad opening and a bonding strength between the bonding pad and the solder is increased.

2. The bonding pad as claimed in claim 1, wherein an annular extension is formed after the protection layer is extended outside the bonding pad opening.

3. The bonding pad as claimed in claim 2, wherein the annular extension has cutouts defined therein to receive therein the solder mask layer.

4. The bonding pad as claimed in claim 1, wherein the protection layer is composed of a copper layer, a nickel layer and a gold layer.

5. The bonding pad as claimed in claim 2, wherein the protection layer is composed of a copper layer, a nickel layer and a gold layer.

6. The bonding pad as claimed in claim 3, wherein current required for plating is transmitted via a ball side to a bump pad side when temperate conductive layer is formed on the solder resistant layer.

7. The bonding pad as claimed in claim 4, wherein current required for plating is transmitted via a ball side to a bump pad side when temperate conductive layer is formed on the solder mask layer.
